(19) United States
(12) Patent Application Publication
(10) Pub. No.: US 2024/0409399 A1
(43) Pub. Date: Dec. 12, 2024

(54) System And Method For Generating Fluid Flow

(71) Applicant: SONICEDGE LTD., Shoham (IL)

(72) Inventor: Mordehai Margalit, Zichron Yaaqov (IL)

(21) Appl. No.: 18/669,701

(22) Filed: May 21, 2024

Related U.S. Application Data
(60) Provisional application No. 63/471,794, filed on Jun. 8, 2023.
(60) Provisional application No. 63/590,793, filed on Oct. 17, 2023.

(51) Int. Cl. B81C 1/00; B81B 7/00

(52) U.S. Cl. CPC B81C 1/00309; B81B 7/0061; B81B 2201/0257; B81B 2201/036; B81B 2203/0127; B81B 2203/0307; B81B 2203/0315; B81B 2203/04; B81C 2201/0105; B81C 2201/014; B81C 2201/0174

(57) ABSTRACT

Techniques described herein generally relate to generating fluid flow in a micro structure. In some examples, a micropump is described that includes at least two membranes and a spacer. The membranes can be configured to oscillate along a first and second directional path to generate fluid flow.

### TECHNICAL FIELD

The present disclosure generally relates to systems and methods for generating fluid flow. In some examples the fluid flow is modulated to generate an audio signal. System and methods of generating a modulated fluid flow are applied in a mobile, wearable, or portable device. In other examples the system and methods of generating a modulated fluid flow are applied in earphones, headsets, hearables, or hearing aids.

### BACKGROUND OF THE DISCLOSURE

US 8861752 describes a micropump configured as a picospeaker which is a novel sound generating device and a method for sound generation. The micropump creates an audio signal by generating an ultrasound acoustic beam which is then actively modulated. The resulting modulated ultrasound signal has a lower acoustic frequency sideband which corresponds to the frequency difference between the frequency of the ultrasound acoustic beam and the modulation frequency. US 20160360320 and US20160360321 describe MEMS architectures for realizing the micropump. US20160277838 describes one method of implementation of the micropump using MEMS processing. US 2016277845 describes an alternative method of implementation of the micropump using MEMS processing. MEMS membranes for generating acoustic signals as well as generating sound using the principles of US 8861752 have been described in US 2016277845. In this disclosure we described a non-limiting implementation of the micropump using a one or more piezo actuators. Hence it is desirable to provide an architecture and method of implementation which reduces the complexity and number of processing steps.

### Glossary

“acoustic signal”—as used in the current disclosure means a mechanical wave traversing either a gas, liquid or solid medium with any frequency or spectrum portion between 10 Hz and 10,000,000 Hz.
“audio” or “audio spectrum” or “audio signal”—as used in the current disclosure means an acoustic signal or portion of an acoustic signal with a frequency or spectrum portion between 10 Hz and 20,000 Hz.
“membrane”—as used in the current disclosure means a flexible structure constrained by at least two points.
“blind”—as used in the current disclosure means a structure with at least one acoustic port through which an acoustic wave traverses with low loss.
“shutter”—as used in the current disclosure means a structure configured to move in reference to the blind and increase the acoustic loss of the acoustic port or ports.
“acoustic medium”—as used in the current disclosure means any of but not limited to; a bounded region in which a material is contained in an enclosed acoustic cavity; an unbounded region where in which a material is characterized by a speed of sound and unbounded in at least one dimension. Examples of acoustic medium include but are not limited to; air; water; ear canal; closed volume around ear; air in free space; air in tube or other acoustic channel.
“fluid”—as used in the current disclosure means any of but not limited to air; water; oil; a gas; a liquid; a liquid with viscosity <100 cp.
“speaker” or “pico speaker” or “micro speaker” or “nano speaker”—as used in the current disclosure means a device configured to generate an acoustic signal with at least a portion of the signal in the audio spectrum.
“micropump”—as used in the current disclosure means a device configured to generate fluid flow including modulated fluid flow. In some examples a micropump configured to generate modulated fluid flow is a picospeaker.

### SUMMARY

Some embodiments of the present disclosure may generally relate to a fluid flow device that includes at least two membranes and a spacer element. A first membrane is positioned is configured to oscillate along a first directional path and at a first frequency. A second membrane is spatially separated from the first membrane and is configured to oscillate along a second directional path. A spacer element is positioned between a first and second membrane defining at least one closed cavity where the dimensions of the cavity are defined by at least a first and a second membrane and at least one dimension of a fluid channels configured to provide fluid flow to the cavity is defined by either a first or second membrane. Other embodiments of the present disclosure may generally relate to a fluid flow device comprising an array of a first and second membrane and spacers wherein the array of membranes operate either independently or driven by a common source. Examples of drive signals include but are not limited to; pulse width modulation and modulated sinusoidal signals. The driving unit is a semiconductor integrated circuit which includes; a communication unit; a charge pump configured to generate a high voltage signal; a switching unit configured to modulate the high voltage signal. The driving unit receives a digital sound data stream and an operating voltage and outputs driving signals for the membrane, and shutter. In some embodiments the membranes operate asynchronously and or independently of each other at one or more frequencies. In other embodiments the membrane operates synchronously at the same frequency. In the synchronous mode of operation, the fluid flow is controlled by any of but not limited to; the relative phase of the membrane operation; the amplitude of the membrane operation; any combination of these.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are therefore not to be considered limiting of its scope, the disclosure will be described with additional specificity and detail through use of the accompanying drawings.

FIG. 1A is an example of a side view of a state of art architecture for a MEMs micropump cell;

FIG. 1B is an example of a side view of a micropump cell configured for a piezo electric drive;

FIG. 1C is an example of an array of micropump cells configured for a piezo electric drive;

FIG. 1D is an example of a top view of a microelectromechanical implementation of an array of micropump cells

FIG. 2 is an example of a top view of one micropump cell;

FIG. 3 is an example of a layer stack for a piezoelectric membrane;

FIG. 4A-4I are an example of a process flow and mask layout for implementing the micropump;

FIG. 5 is an example of alternative membrane and spoke configurations.

FIG. 6 is an alternative example of the configuration of three layers for a cell of an ultrasonic pump;

FIG. 7A is a top view of an alternative configuration for a micropump implemented in one layer;

FIG. 7B is side view cut out of the alternative configuration for a micropump implemented in one layer from FIG. 7A;

FIG. 7C is an example of side view cut out of a chamber and flow path for a micropump implemented in one layer from FIG. 7A;

FIG. 7D is an alternative example of side view cut out of a chamber and flow path for a micropump implemented in one layer from FIG. 7A.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other examples may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure. This disclosure is drawn, inter alia, to methods, apparatus, computer programs, and systems of generating an audio signal.

Some embodiments of the present disclosure may generally relate to a fluid flow device that includes at least two membranes and a spacer element. A first membrane is positioned is configured to oscillate along a first directional path and at a first frequency. A second membrane is spatially separated from the first membrane and is configured to oscillate along a second directional path. A spacer element is positioned between a first and second membrane defining at least one closed cavity where the dimensions of the cavity are defined by at least a first and a second membrane and at least one dimension of a fluid channels configured to provide fluid flow to the cavity is defined by either a first or second membrane. Other embodiments of the present disclosure may generally relate to a fluid flow device comprising an array of a first and second membrane and spacers wherein the array of membranes operate either independently or driven by a common source. Examples of drive signals include but are not limited to; pulse width modulation and modulated sinusoidal signals. The driving unit is a semiconductor integrated circuit which includes; a communication unit; a charge pump configured to generate a high voltage signal; a switching unit configured to modulate the high voltage signal. The driving unit receives a digital sound data stream and an operating voltage and outputs driving signals for the membrane, and shutter. In some embodiments the membranes operate asynchronously and or independently of each other at one or more frequencies. In other embodiments the membrane operates synchronously at the same frequency. In the synchronous mode of operation, the fluid flow is controlled by any of but not limited to; the relative phase of the membrane operation; the amplitude of the membrane operation; any combination of these.

In a non-limiting example, we describe the micropump as modulated flow device. A first and or second membrane is driven by an electric signal that oscillates at a frequency Ω and hence moves at b cos (2π*Ωt), where b is the amplitude of the membrane movement, and t is time. The electric signal is further modulated by a portion that is derived from an audio signal a (t). The acoustic signal is characterized as:

$$s ( t ) = ba ( t ) Cos ( 2 π * Ω t ) \qquad ( 1 )$$

Applying a Fourier transform to Equation (1) results in a frequency domain representation

$$S ( f ) = b / 2 * [ A ( f - Ω ) + A ( f + Ω ) ] \qquad ( 2 )$$

Where A(f) is the spectrum of the audio signal. Equation (2) describes a signal with an upper and lower side band around a carrier frequency of Ω. In one example the second membrane can be described as a modulator operating the signal of eq(1). results in

$$S ( t ) = ba ( t ) Cos ( 2 π * Ω t ) ( l + m Cos ( 2 π * Ω t ) ) \qquad ( 3 )$$

Where I is the loss of the modulator and m is the modulation function and due to energy conservation I+m<1. In the frequency domain

$$S ’ ( f ) = b / 4 * [ m A ( f ) + m A ( f + 2 Ω ) + A ( f - Ω ) + A ( f + Ω ) ] \qquad ( 4 )$$

Where b/4*m A(f) is an audio signal. The remaining terms are ultrasound signals where m A(f+2Ω) is at twice the modulation frequency and A(f−Ω)+A(f+Ω) is the original unmodulated signal. Additional acoustic signals may be present due to any but not limited to the following; ultrasound signal from the shutter movement; intermodulation signals due to nonlinearities of the acoustic medium; intermodulation signals due to other sources of nonlinearities including electronic and mechanical. In one example where a(t)=1, i.e. the acoustic signal is constant, the device operates as a constant flow pump. For a more detailed description we need to examine the dynamics of the membranes as defined by the interaction of a driving force; mechanical dynamics of the membrane; and fluid membrane interaction. Examples of driving force include but are not limited to electrostatic; thermoelectric or piezo electric. Examples of mechanical dynamics include but are not limited to; second order mechanical system; second order mechanical system with damping; higher order mechanical system. The mechanical dynamics are configured to include at least one resonance frequency for each membrane. The membrane dynamics are simulated using either a computational fluid dynamics (CFD) model or a simplified coupled differential equation describing mechanical movement and membrane fluid coupling. One example of the coupled equations with only second order dynamics for the membranes is described in equations (1) to (4) includes but is not limited to;

$${\ddot{x}}_{1} + {b}_{1} {\dot{x}}_{1} + {k}_{1} {x}_{1} = {F}_{1} ( t ) + {FP}_{1} \qquad ( 5 )$$

$${\ddot{x}}_{2} + {b}_{2} {\dot{x}}_{2} + {k}_{2} {x}_{2} = {F}_{2} ( t ) + {FP}_{2} \qquad ( 6 )$$

$${\ddot{x}}_{3} + {b}_{3} {\dot{x}}_{3} + {k}_{3} {x}_{3} = {F}_{3} ( t ) + {FP}_{3} \qquad ( 7 )$$

$$\ddot{P} + {b}_{p} \dot{P} + {k}_{p} P = {FP}_{p} \qquad ( 8 )$$

Where the index (1,2,3) refers to first, second or third membrane, bₓ is the damping coefficient, kₓ is the spring coefficient, Fₓ is the actuation force, FPₓ is the fluid membrane interaction. Equation (4) describes the second order dynamics of the fluid enclosed between the membranes where bₚ and kₚ are defined by the membrane displacement and FPₚ is the aggregate membrane fluid interaction. Equations (5-8) describe the action of membranes to generate fluid flow \dot{P}.

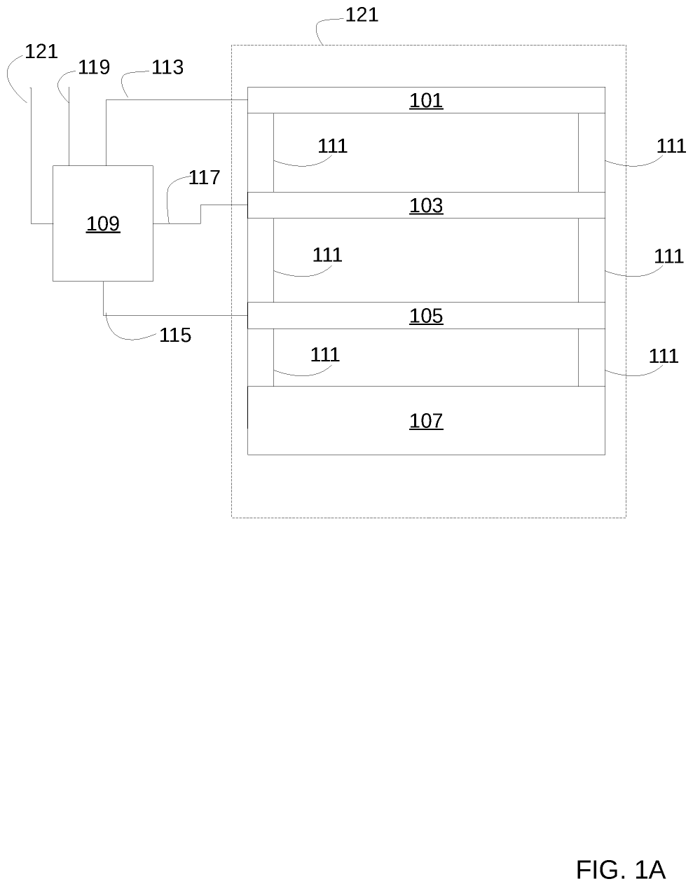

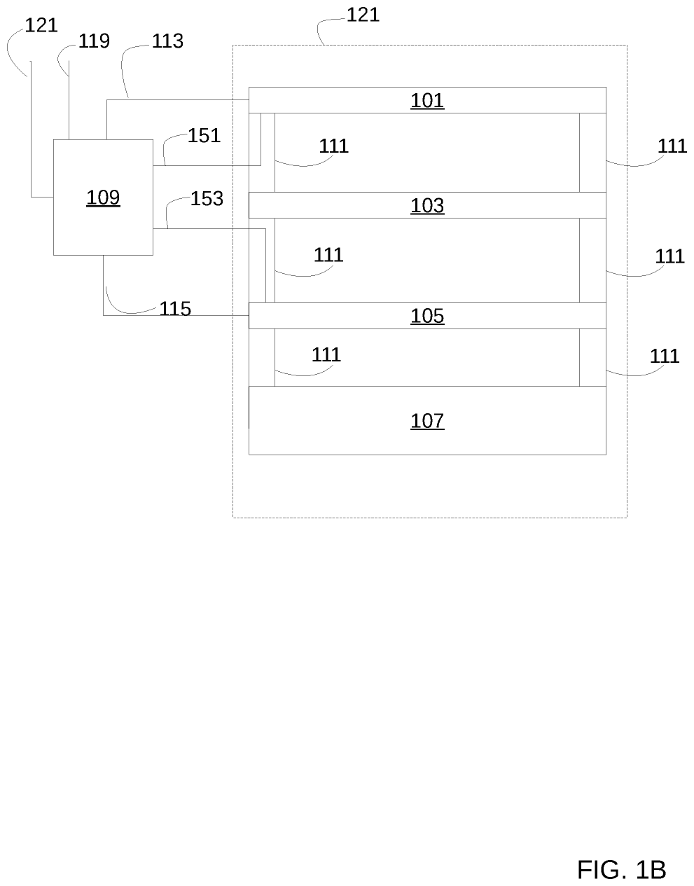

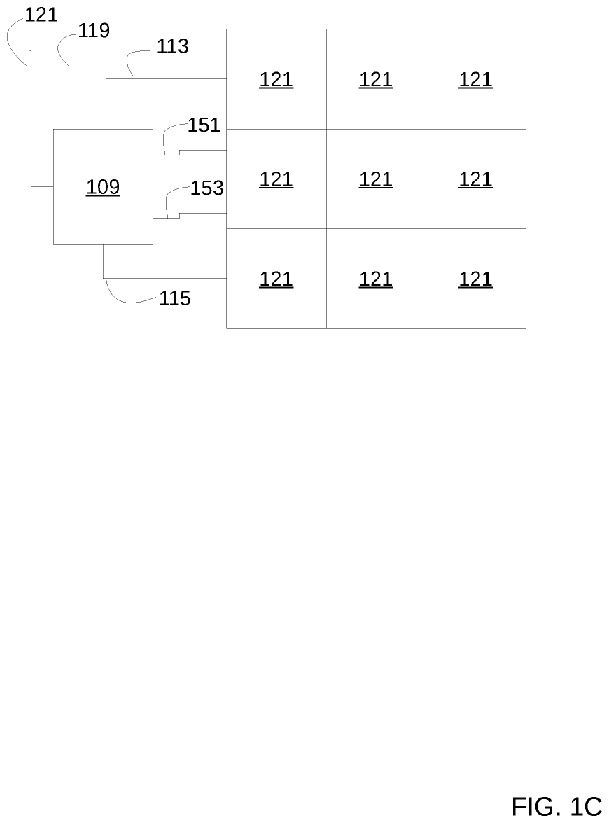

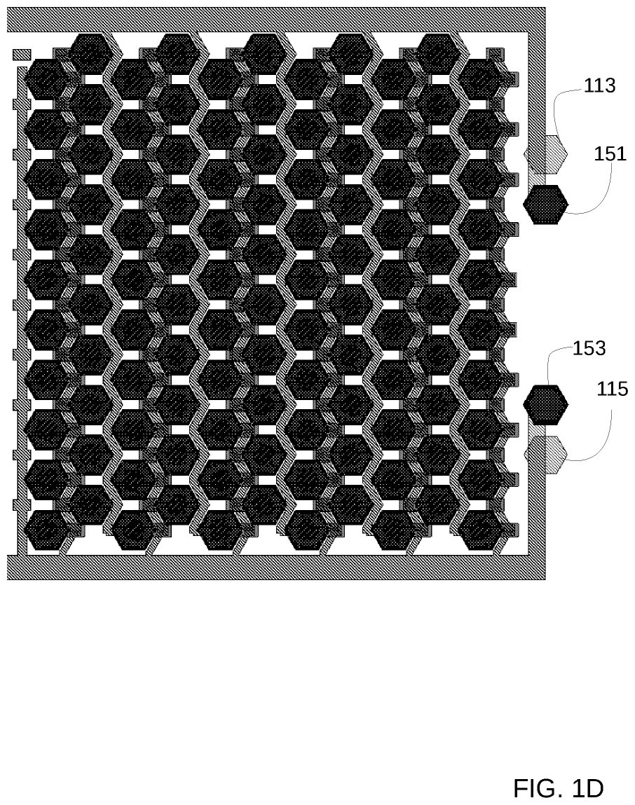

FIG. 1A is an example of side view of a state of art architecture for a MEMs micropump cell (121). The micropump cell is composed of at least three layers. a first membrane (105), which generates the acoustic signal described in Equation (1) by moving in the direction of arrows (190). A spacer (103) and second membrane (101) move relative to each other and modulate the acoustic signal as described in Equation (3). In an alternative description a first membrane (105) is positioned is configured to oscillate along a first directional path and at a first frequency. A second membrane (101) is spatially separated from the first membrane and is configured to oscillate along a second directional path. A spacer element (103) is positioned between a first and second membrane defining at least one closed cavity where the dimensions of the cavity are defined by at least a first and a second membrane and at least one dimension of a fluid channels configured to provide fluid flow to the cavity is defined by either a first or second membrane. In one example driving device (109) provides one voltage signal to membrane (15) and a second voltage signal to shutter (101) and the voltage to blind (103) is set at zero or ground. The first and second voltage signals provide the driving force to generate the acoustic sound of Equation (1) and the modulation function of Equation (3) respectively. In an additional example a fourth layer; handle (107) is included. A driver device (109) is electrically connected to a digital audio source via line (119), low voltage source via line (121), membrane layer (105) via line (115), blind layer (103) via line (117) and shutter layer (101) via line (113). The micropump device is composed of multiple micropump cells (121). FIG. 1B is an example of a top view of a matrix arrangement of a plurality of cells (121) adapted from US 2016277845. The cells (121) are electrically connected in parallel so that a first drive voltage is applied to all membranes (FIG. 1A 105) in the connected cells (121) and a second drive voltage is applied to all shutters (FIG. 1A 101) in the connected cells (121).

FIG. 1B is an example of a side view of a micropump cell configured for a piezo electric drive as taught in this disclosure. The main difference in the device architecture is that the spacer (103) is not used as an electrical ground. Hence in a piezoelectric drive configuration a spacer (103) is composed of any material including but not limited; metal; ceramic; polymer; plastic; semiconductor; Silicon; polysilicon, SiO2, SiN, AlN, AlSCN, TiO2, Au, Ni, AlCu, Al and combinations of these materials. Since the spacer (103) is not used as a ground plane, The spacer can be in in whole or in part electrically isolating. Each of the membranes (101, 105) is composed of a piezo electric stack described later, where the stack includes at least, a piezo material, a bottom electrode connected to one electrical connection (113, 115, 151, 153) and a top electrode connected to a second electrical connection (113, 115, 151, 153) for a total of 4 connections 2 for each membrane.

FIG. 1C is an example of an array of two or more micropump cells configured for a piezo electric drive where in each cell, each of the at least two membranes (101, 105) has a top and bottom electrode electrically connected to at least one other top or bottom electrode respectively in at least a second cell. In one example all membrane (101) bottom electrodes are connected to one electrical connection (113), all membrane (101) top electrodes are connected to second electrical connection (151), all membrane (105) bottom electrodes are connected to third electrical connection (115), all membrane (105) top electrodes are connected to fourth electrical connection (153).

FIG. 1D is an example of a top view of a microelectromechanical implementation of an array of micropump cells displaying the membranes and the electrical connection pads (113, 115, 151, 153).

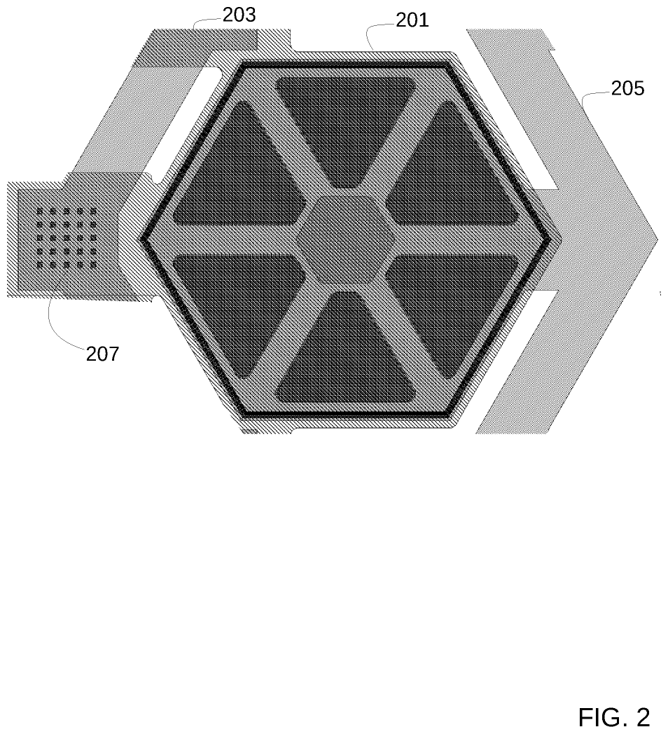

FIG. 2 is an example of a top view of one micropump cell from the array of micropump cells in FIG. 1. D. The micropump cell includes a membrane (201) corresponding to first or second membrane (FIG. 1B. 101, 105). A first electrical conductor (205) connecting to a bottom electrode of the membrane (201) and a second electrical conductor (203) connecting to a top electrode of the membrane (201). In one further example, electrical connection between electrical conductor of top membrane and electrical conductor of bottom electrode is facilitated by conductive vias (207). Examples of electrical conductors include but are not limited to Al, AlCu, AlSiCu, other Al compositions, doped polySi, Si, dope Si, Au, Ag, Cu, Ni, Ti, Cr or layers or combinations of these materials. Examples of materials for vias (207) include but are not limited to Tu, Ti, Cu, Ni, or combinations of these materials.

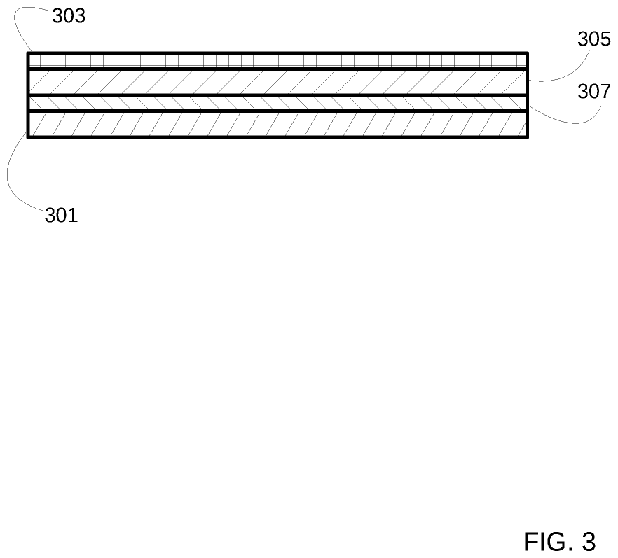

FIG. 3 is an example of a layer stack for a piezoelectric membrane. In one example the stack is a uni-morph structure. stack includes at least a support layer (301), a bottom electrode (307), a piezo layer (305), and a top electrode (303). In an alternative example the structure would be a bi-morph structure with no support layer, a bottom electrode, a first piezo electric layer, a middle electrode, a second piezo electric layer and a top electrode. In a uni-morph, movement is obtained by asymmetric stress loading of the piezo material (305). Hence when voltage is applied between a top electrode (303) and bottom electrode (301) the piezo expands or contracts in the plane orthogonal to the electrodes. By having the piezo (305) located to one side of the axis of symmetry of the structure we obtain deformation. Examples of piezo material include but are not limited to, AlN, AlScN, KNN, PZT, PVDS, or combinations of these materials. Examples of materials for top and or bottom electrode (301, 303) include but are not limited to Pt, Mo, AI, Ti, Cr, Au, Ag, Cu, Ni or combinations of these materials. Examples of materials for a support layer include but are not limited to a piezo material, AlN, AlSCN, KNN, PZT, PVDS, Si, SiO2, TiN, SiN or combinations of these materials. In one example the material chosen for the support layer meets at least one of the following criteria; electrically isolating, resistant to HF and or VHF etch, flexible, with a young modulus compatible with the piezo material. In one example support layer is made from the piezo material. Since the support layer does not have electrodes from both sides, it will not deform and will just provide the asymmetric loading needed to enable a deformation.

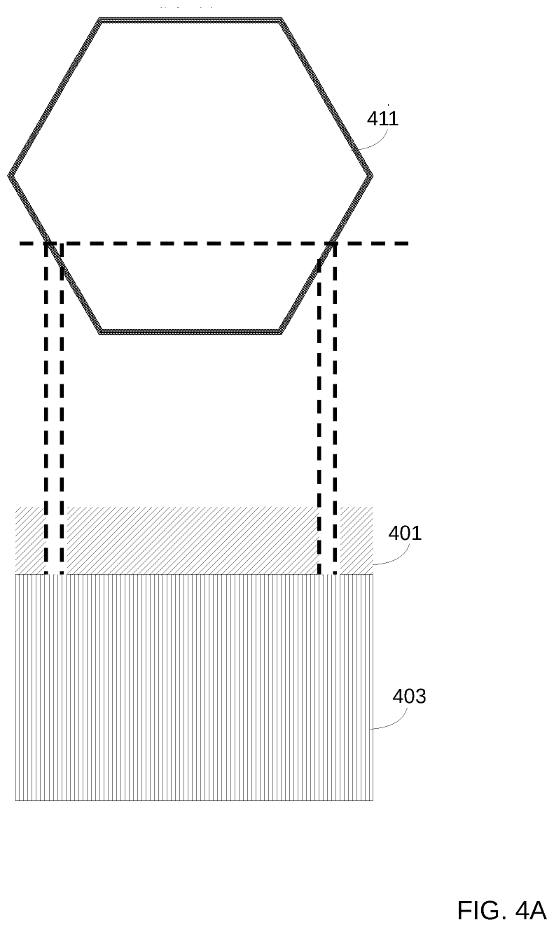

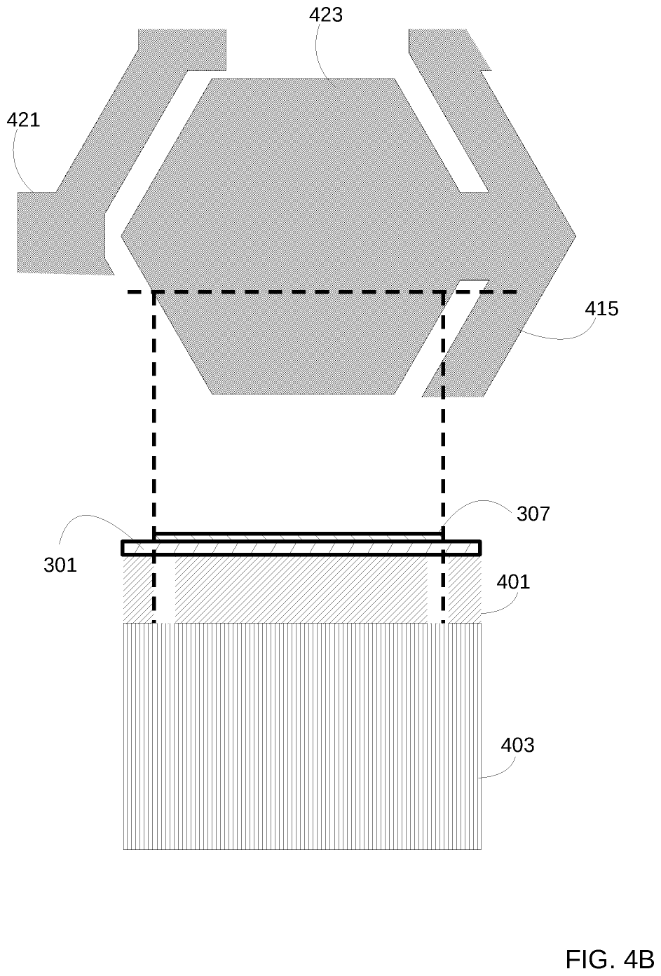

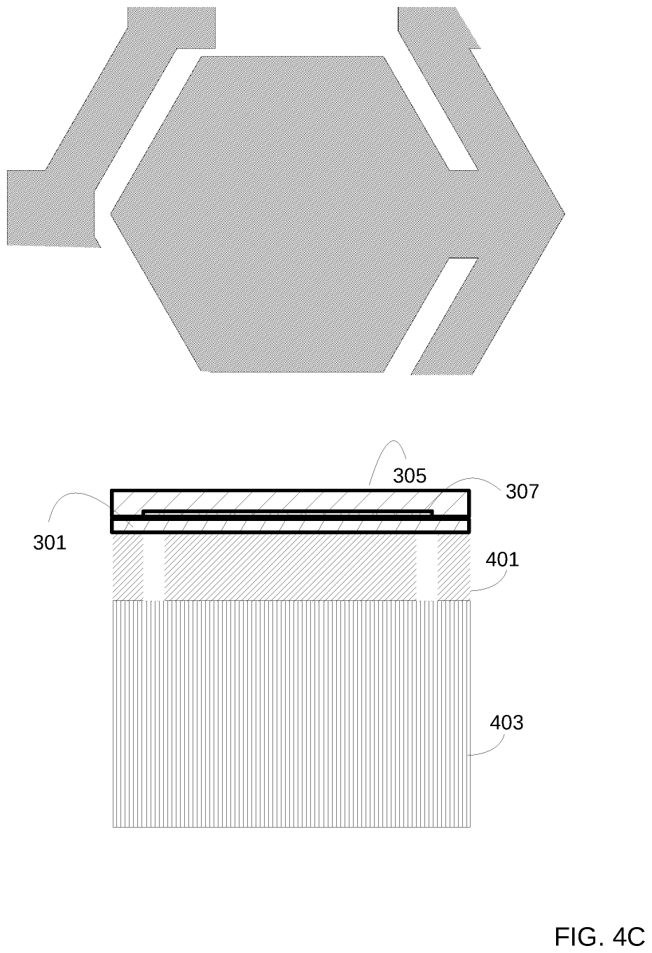

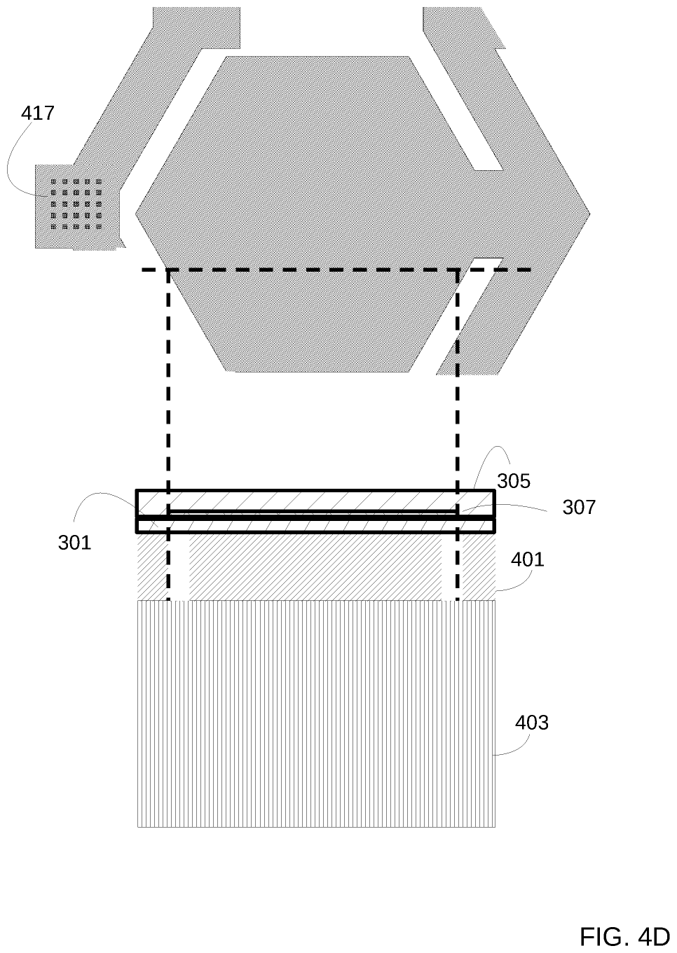

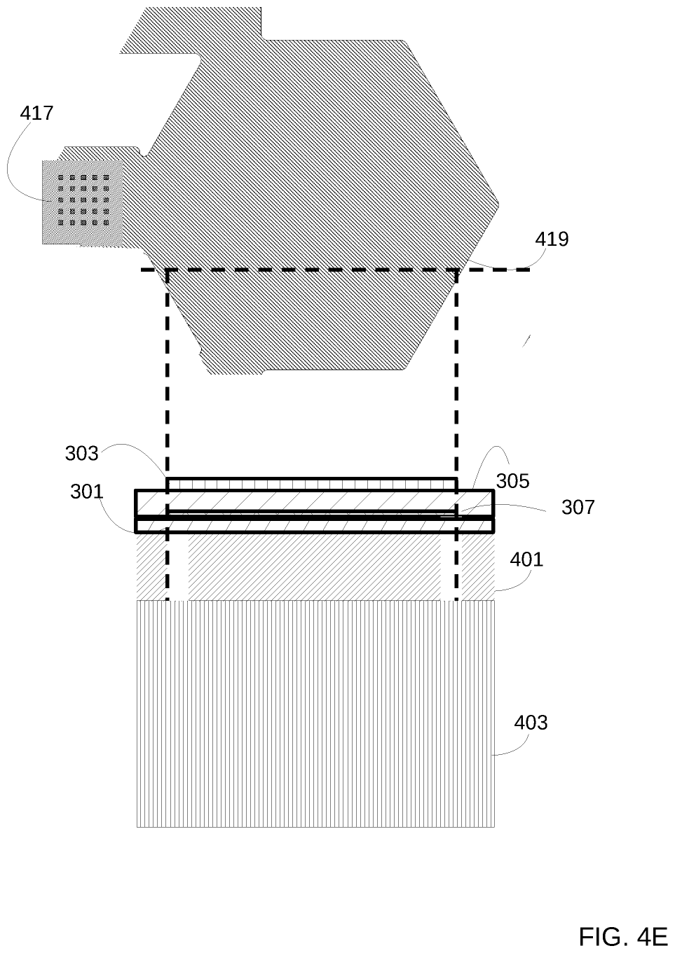

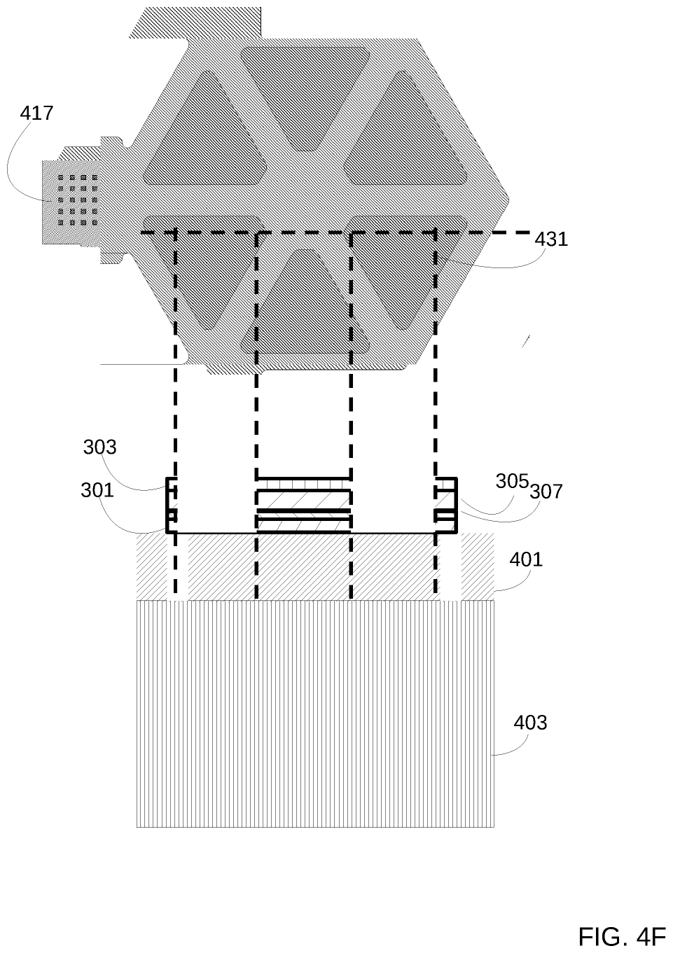

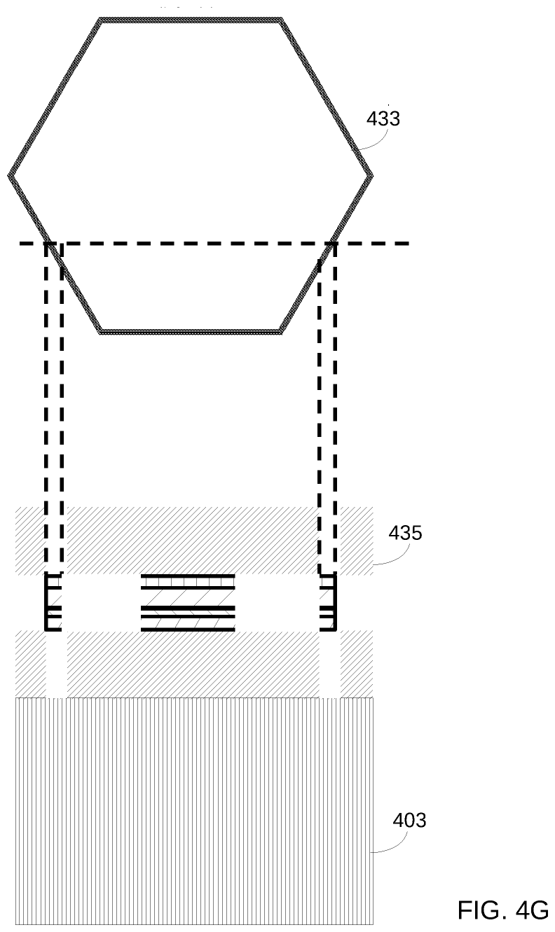

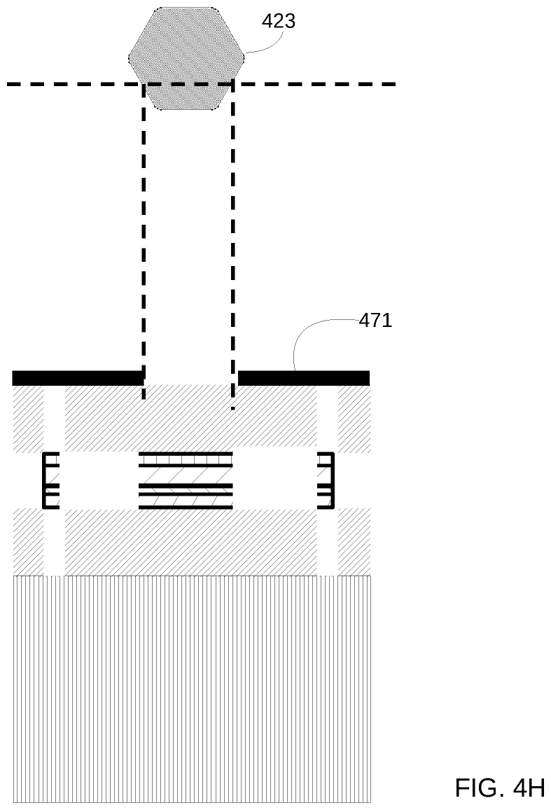

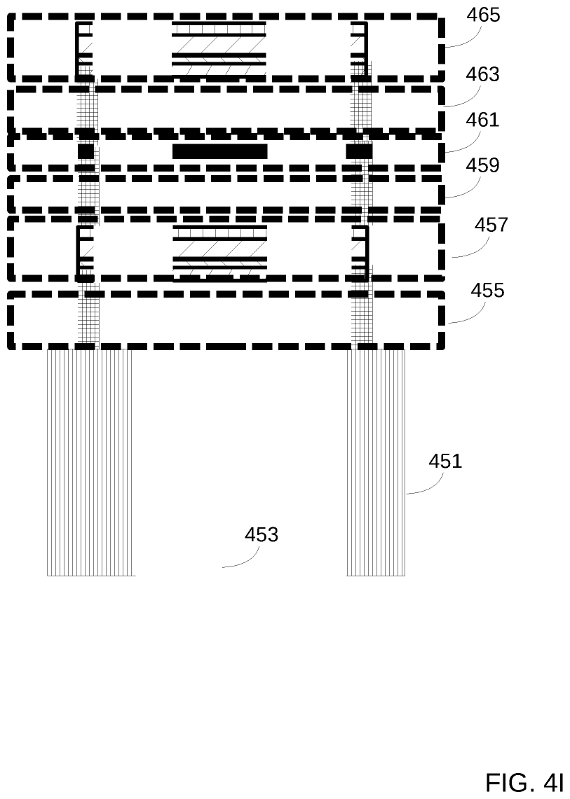

FIG. 4A-4I are an example of a process flow and mask layout for implementing the micropump. FIG. 4A is an example of a first pattern (411) implemented in a lithography mask and used for defining a pattern on a substrate (403) used for manufacturing a micropump. A substrate (403) is coated with a first sacrificial layer (401). Examples of substrates include but are not limited to; Silicon; Sapphire; Glass; polymer; paper or combinations of these. A first sacrificial layer (403) is comprised of any off but not limited to SiO2, polymer, PI, SU8, aSi, polySi or combinations of these materials. In a further example the first sacrificial layer (403) is etched by an isotropic etch including but not limited to HF, VHF, O2 plasma, O2 plasma with CHF4 or CHF6 and or Argon, XeFe. A first pattern (411) is defined in the first sacrificial layer (401) using lithography and subsequent etching process. A first etch stop layer is deposited on top of first sacrificial layer (401) ensuring the pattern in the first sacrificial layer (401) is filled with the first etch stop material. Examples of deposition include but are not limited to PVD, CVD, Sputtering, PECVD, plating or combinations of these processes. The material used for the etch stop layer is resistant or partially resistant to the etch process used for removing the first sacrificial layer. In one example the sacrificial layer is SiO2, the etch process is based on VHF or HF and examples of materials include but are not limited to Tungsten, Copper, Silicon, Aluminum, Titanium, Tantalum, SiN, Silicon rich Nitride or combinations of these materials. In an alternative example the sacrificial layer is a polymer, the etch process is based on Oxygen based plasma and examples of materials include but are not limited to Tungsten, Copper, Silicon, Aluminum, Titanium, Tantalum, SiN, Silicon rich Nitride, Silicon Oxide or any non-organic material or combinations of these materials. In an alternative example the sacrificial layer is aSi, or Si, the etch process is based on XeFe and examples of materials include but are not limited to any non Si material. In a further example a chemical mechanical polishing and or etch back is used to remove any etch stop material from the top of the first sacrificial layer (401) leaving etch stop material only in the recess defined by the first pattern (411). FIG. 4B is an example of a bottom electrode pattern (415) and layer structure. A support layer (301) is deposited on first sacrificial layer (401). In one example support layer is electrically isolating hence ensuring the bottom electrode is not electrically connected to first sacrificial layer or to etch stop material. This enables more flexibility in etch stop material choice to include electrically conducting materials such as metals, SiRN or Silicon. A bottom electrode layer (307) is deposited on support layer (301) and patterned with bottom electrode pattern (415, 421, 423). Bottom electrode pattern includes first electrical connection (421) for bottom electrode as well as second electrical connection (423) for top electrode. FIG. 4C depicts a piezo layer (305) deposited on patterned bottom electrode (307). FIG. 4D depicts conducting vias (417) patterned in piezo layer (305). Since piezo layer is electrically isolating, conducting vias (417) are holes in piezo layer which enable electrical contact between top electrode and second electrical connection (423). Deposition of top electrode (303) will create electrical connection through the vias an appropriate pattern as shown in FIG. 4E. The membrane structure (431) is defined with photolithography and etched through top electrode (303), piezo layer (305), bottom electrode (307), support layer (301). FIG. 4F is an example of a second sacrificial layer (435) deposited on the top electrode and patterned structure and patterned with second etch stop pattern (433). A second etch stop layer is deposited and then removed from top side of second sacrificial layer leaving etch stop material in etch stop pattern (433). FIG. 4G is an example of a spacer layer (471) deposited on second sacrificial layer and patterned with spacer pattern (423). A third sacrificial layer, etch stop material and second piezo stack are deposited on patterned spacer layer (471). The substrate is etched from the back side and sacrificial material is removed using a selective etch process which has a high etch rate of the sacrificial layer but has low etch rate for the etch stop material the support material and or the piezo material. In one example the ratio of fast to slow etch rates are any of but not limited to larger than 5; larger than 10; larger than 100. The resulting micropump structure is shown in FIG. 41 with a substrate (451), a back side hole in substrate (453), a first gap layer (455), a first piezo layer (457), a second gap layer (459), a spacer layer (461), a third gap layer (463) a second piezo layer (465).

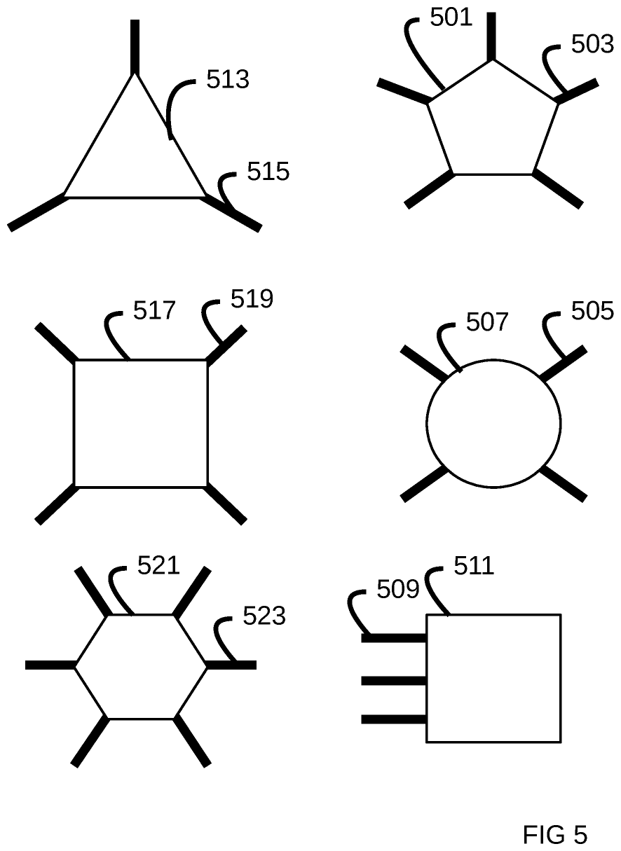

FIG. 5 is an example of alternative piezoelectric membrane (FIG. 2, 201) configurations. Examples include but are not limited to; a pentagon (501) with at least one spoke (503); a circle (507) with at least one spoke (505); a rectangle (511) with at least one spoke (509); a triangular shaped membrane (513) and at least one spoke (515); a square (517) with at least one spoke (519); a hexagon (521) with at least one spoke (523). The at least one spoke (505, 515, 519, 523) or more can be distributed symmetrically around a membrane (507, 511, 513, 517, 521); In another example a spoke (503, 505, 515, 519, 523) extends from at least one corner of a membrane (501, 507, 513, 517, 521). In an alternative example a spoke (509) extends from at least one member of the enclosing perimeter of a membrane (511). An aperture (FIG. A 121) is configured for a membrane where the aperture (FIG. A 121) is smaller than a corresponding membrane (501, 507, 511, 513, 517, 521) by an overlap dimension as previously defined.

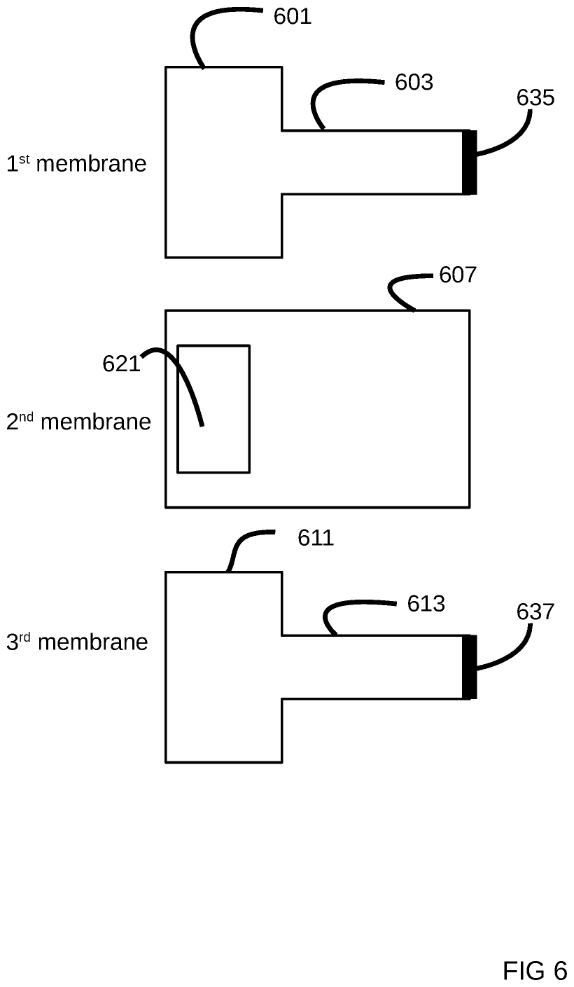

FIG. 6 is an alternative example of the configuration of three layers for a cell of an ultrasonic pump. The layers include but are not limited to; a first membrane (601) and spoke (603) comprising a first layer; a second membrane (607) configured with at least one aperture (621) comprising a second layer; a third membrane (611) and spoke (613) comprising a third layer. The layers are aligned so that there is overlap between first and third membrane (601, 611) and aperture (621), where the minimum overlap distance is as defined previously. In a further example, spoke (603) is connected to a first anchor (635) and is except for anchor (635) free to move. Spoke (613) is connected to a first anchor (637) and is except for anchor (637) free to move. In this example, since the membrane is asymmetrically anchored the movement will be asymmetric with the area of the membrane furthest from the anchor moving the most. In a further example location of aperture (621) is configured to provide the smallest overlap at the area of the membrane furthest from the anchor. In one example the overlap at the furthest location of the membrane is termed effective overlap and is at least but not limited to; 100 nm; 1 micron; 5 micron; 10 micron; 100 micron; less than 1 mm. Overlap at other locations are blocking overlaps and are at least 2 times larger than the effective overlap. In a further example spoke length is at least; 5 micron; 10 micron; 50 micron; 100 micron. In an alternative example the resonance frequency of the membrane and spoke is designed to be any of but not limited to between 200 KHz to 300 KHz, 300 KHz to 400 KHz, 400 KHz to 500 KHz, above 500 KHz, below 200 KHz.

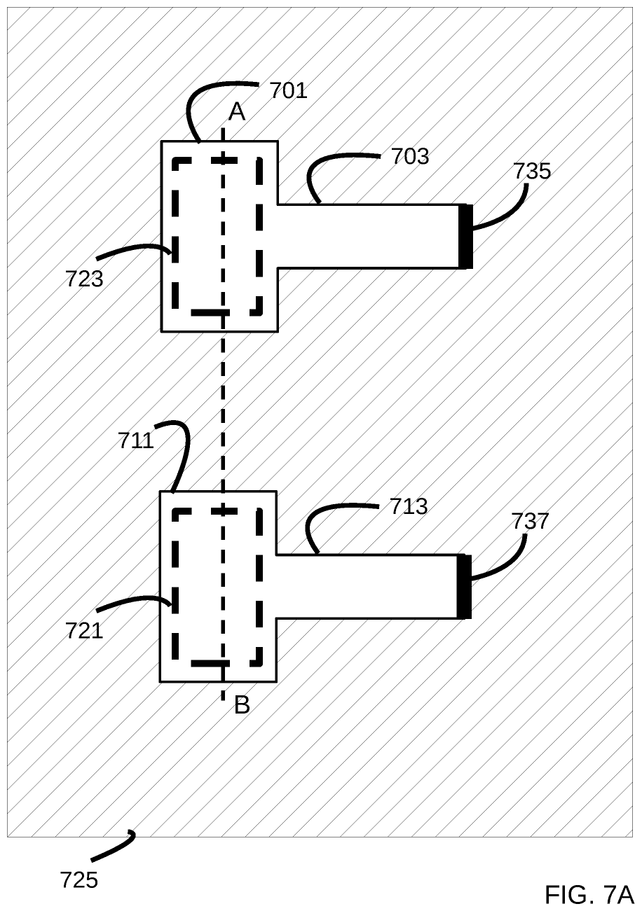

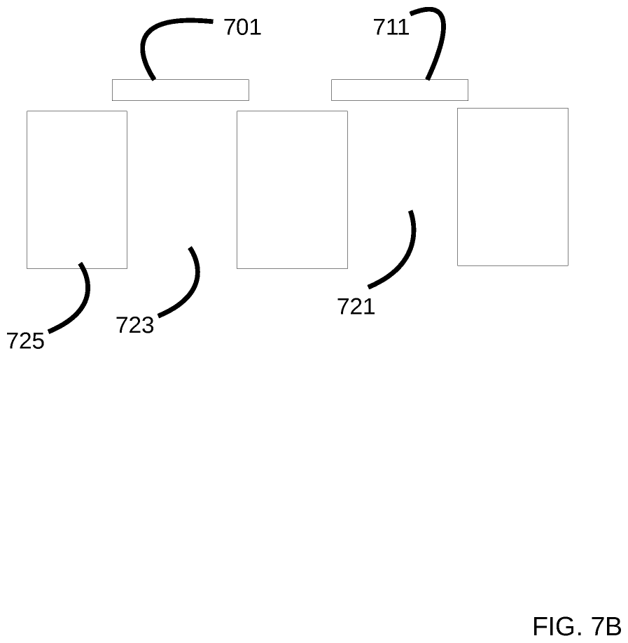

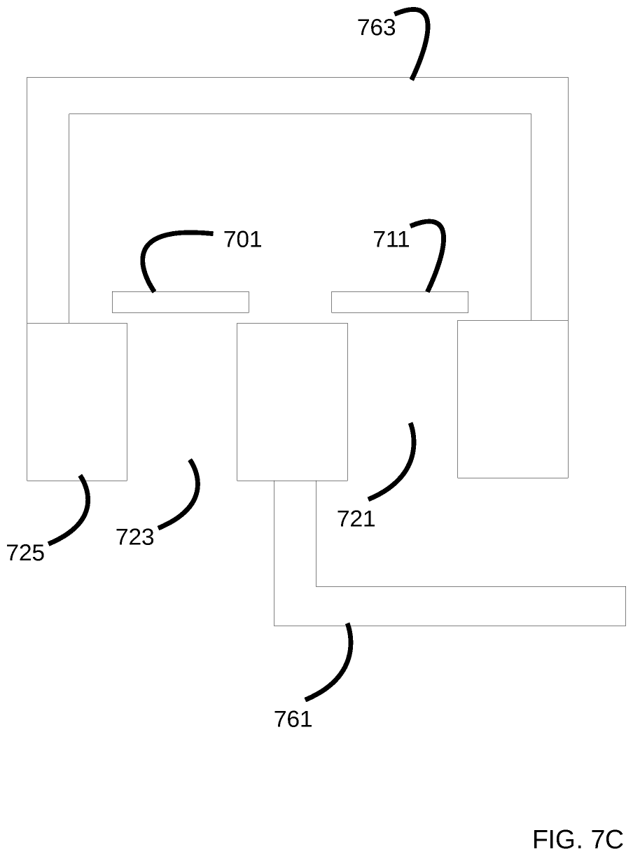

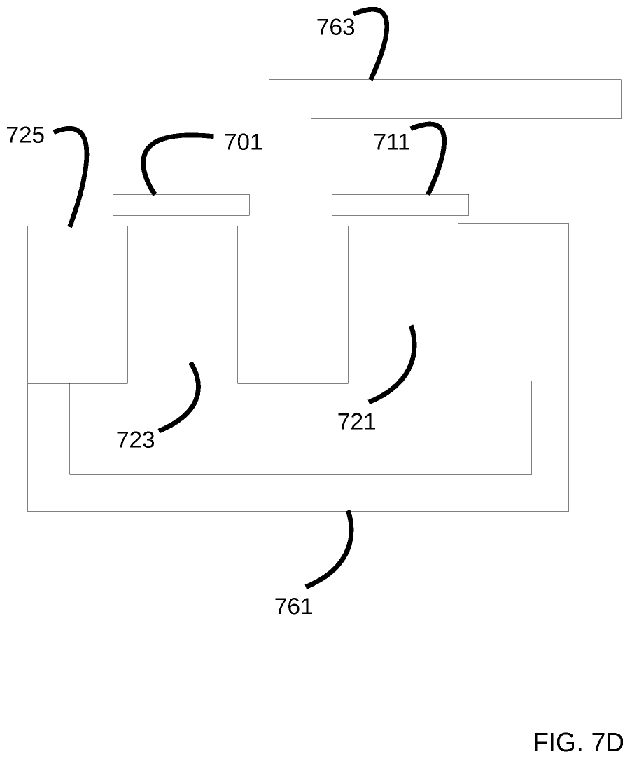

FIG. 7A is a top view of an alternative configuration for a micropump implemented in one layer. While in previous examples the membranes where located on top of each other, in an alternative examples the membranes are located in the same layer but at spatially distinct locations. In one example one membrane (701) replaces the previously designated bottom membrane (FIG. 6, 601), a second membrane (711) replaces the previously designated top membrane (FIG. 6 611) and the volume between them is defined with supporting structures on either top or below membranes. Membranes are located on substrate (725). In one example substrate (725) is any of but not limited to; Silicon; Ceramic; Al2Ox; AlN; FR4; PCB; Kapton; glass; polymer; metal or combination of these. Below each membrane (701, 711) a hole (721, 723) is defined in the substrate extending through the substrate. The hole (721, 723) will form either the flow conduit or chamber between membranes. Each membrane (701, 711) is realized as a piezoelectric membrane as described previously. In an alternative example the membranes (either 701 and or 711) are implemented as an electrostatic membrane. Operation of membranes is the same as described previously since the volume of the cavity between the membranes does not have an impact on the resulting pump flow or audio signal. FIG. 7B is side view cut out of the alternative configuration for a micropump implemented in one layer from FIG. 7A highlighting the hole (721, 723) through the substrate. FIG. 7C is an example of side view cut out of a chamber and flow path for a micropump implemented in one layer from FIG. 7A, where the cavity between the membranes (701 and 711) is defined by a top cover (763) located above the membranes (701 and 711). The intake and output conduits are located at the back side of the wafer at the output of the substrate holes (721, 723) are acoustically separated by an acoustic structure (761) separating incoming and outgoing flow and preventing an acoustic short circuit. FIG. 7D is an example of side view cut out of a chamber and flow path for a micropump implemented in one layer from FIG. 7A, where the cavity between the membranes (701 and 711) is defined by a bottom cover (761) located above the holes (721 and 723) below the membranes (701, 711). Membrane (721, 723) output is acoustically separated by an acoustic structure (763) separating incoming and outgoing flow and preventing an acoustic short circuit. Membrane (701, 711) may be extended to include 2 or more membranes for each group. When using membrane (701, 711) arrays, membrane layout should enable a common input or output flow and common volume connecting all membranes (701, 711).

To sum in one example, presented is a micropump comprised of: a substrate with at least one back side hole; a first piezoelectric layer stack; a spacer layer; a second piezoelectric stack; wherein a gap layer is in contact with at least two layers or a layer and a substrate and substrate, first piezoelectric stack and second piezoelectric stack are electrically isolated. In a further example the gap layer is comprised of at least two materials; a first material with high etch rate to an etchant and second material with slow etch rate to same etchant. In a further example the gap layer is comprised of any of but not limited to Tungsten, Copper, Nickel, SiRN, SiN, Aluminum, Ag, Au or combinations of these materials. In a further example the first or second piezo electric layer stack includes at least a support layer, bottom electrode, piezoelectric layer, top electrode. In a further example the piezoelectric layer comprising of any but not limited to AlN, AlScN, PZT, KNN, PVDF. In a further example the first or second piezo electric layer stack includes at least a bottom electrode, first piezoelectric layer, middle electrode, second piezoelectric material, top electrode. In a further example the piezoelectric layer comprising of any but not limited to AlN, AlScN, PZT, KNN, PVDF. In an alternative example a method for manufacturing a micropump comprised of depositing a first gap layer comprised of a sacrificial material and etch stop material; depositing and patterning first piezoelectric layer stack; depositing a second gap layer comprised of a sacrificial material and etch stop material; depositing a spacer layer; depositing a third gap layer comprised of a sacrificial material and etch stop material; depositing and patterning a second piezoelectric layer stack; removing sacrificial material using isotropic etch. In a further example the gap layer comprising of at least two materials; a first material with high etch rate to an etchant and second material with slow etch rate to same etchant. In a further example the gap layer is comprised of any of but not limited to Tungsten, Copper, Nickel, SiRN, SIN, Aluminum, Ag, Au or combinations of these materials. In a further example the first or second piezo electric layer stack includes at least a support layer, bottom electrode, piezoelectric layer, top electrode. In a further example the piezoelectric layer comprising of any but not limited to AlN, AlScN, PZT, KNN, PVDF. In a further example the first or second piezo electric layer stack includes at least a bottom electrode, first piezoelectric layer, middle electrode, second piezoelectric material, top electrode. In a further example the piezoelectric layer comprising of any but not limited to AlN, AlScN, PZT, KNN, PVDF. In an alternative example, a micropump is comprised of a substrate with at least two through holes; at least two piezoelectric membranes; wherein an acoustic volume is defined between the at least two membranes; and the at least two membranes are operated independently to generate a fluid flow. In a further example between membrane and substrate is a gap layer. In a further example the gap layer comprising of any of but not limited to Tungsten, Copper, Nickel, SiRN, SIN, Aluminum, Ag, Au or combinations of these materials. In a further example the first or second piezo electric layer stack includes at least a support layer, bottom electrode, piezoelectric layer, top electrode. The micropump of claim 15, wherein the piezoelectric layer comprising of any but not limited to AlN, AlScN, PZT, KNN, PVDF.

There is little distinction left between hardware and software implementations of aspects of systems; the use of hardware or software is generally (but not always, in that in certain contexts the choice between hardware and software can become significant) a design choice representing cost versus efficiency tradeoffs. There are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; if flexibility is paramount, the implementer may opt for a mainly software implementation; or, yet again alternatively, the implementer may opt for some combination of hardware, software, and/or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and or firmware would be well within the skill of one of skill in the art in light of this disclosure. In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Versatile Disk (DVD), a digital tape, a computer memory, etc.; and a transmission type medium such as a digital and/or an analog communication medium (e.g., a fiber optic cable, a waveguide, a wired communications link, a wireless communication link, etc.).

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical data processing system may be implemented utilizing any suitable commercially available components, such as those typically found in data computing/communication and/or network computing/communication systems.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to disclosures containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”. Speaker and micropump are interchangeable and can be used in in place of the other.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A micropump comprising:
a substrate with at least one back side hole;
a first piezoelectric layer stack;
a spacer layer;
a second piezoelectric layer stack; and
a gap layer in contact with at least one of the layer stacks and the spacer layer, or with one of the layer stacks and the substrate,
wherein the substrate, the first piezoelectric layer stack and the second piezoelectric layer stack are electrically isolated.

2. The micropump of claim 1, wherein the gap layer comprises at least two materials; a first material with high etch rate to an etchant and second material with slow etch rate to same etchant.

3. The micropump of claim 1, wherein the gap layer comprises of any of Tungsten, Copper, Nickel, SiRN, SiN, Aluminum, Ag, Au or combinations of these materials.

4. The micropump of claim 1, wherein each of the first or second piezo electric layer stack include at least a support layer, bottom electrode, piezoelectric layer, top electrode.

5. The micropump of claim 4, wherein the piezoelectric layer comprising of any of AlN, AlScN, PZT, KNN, PVDF.

6. The micropump of claim 1, wherein the first or second piezo electric layer stack includes at least a bottom electrode, first piezoelectric layer, middle electrode, second piezoelectric material, top electrode.

7. The micropump of claim 6, wherein the piezoelectric layer comprises any of AlN, AlScN, PZT, KNN, PVDF.

8. A method for manufacturing a micropump comprising:
depositing a first gap layer comprised of a sacrificial material and etch stop material;
depositing and patterning a first piezoelectric layer stack;
depositing a second gap layer comprised of a sacrificial material and etch stop material;
depositing a spacer layer;
depositing a third gap layer comprised of a sacrificial material and etch stop material;
depositing and patterning second piezoelectric layer stack; and
removing sacrificial material using isotropic etch.

9. The method for manufacturing a micropump of claim 8, wherein the gap layer comprises at least two materials; a first material with high etch rate to an etchant and second material with slow etch rate to same etchant.

10. The micropump of claim 8, wherein the gap layer comprises of any of Tungsten, Copper, Nickel, SiRN, SiN, Aluminum, Ag, Au or combinations of these materials.

11. The micropump of claim 8, wherein the first or second piezo electric layer stack includes at least a support layer, bottom electrode, piezoelectric layer, top electrode.

12. The micropump of claim 11, wherein the piezoelectric layer comprises any but not limited to AlN, AlScN, PZT, KNN, PVDF.

13. The micropump of claim 8, wherein the first or second piezo electric layer stack includes at least a bottom electrode, first piezoelectric layer, middle electrode, second piezoelectric material, top electrode.

14. The micropump of claim 13, wherein the piezoelectric layer comprising of any but not limited to AlN, AlScN, PZT, KNN, PVDF.

15. A micropump comprising:
a substrate with at least two through holes; and
at least two piezoelectric membranes;
wherein an acoustic volume is defined between the at least two membranes and wherein the at least two membranes are operated independently to generate a fluid flow.

16. The micropump of claim 15, further comprising a gap layer between a membrane and the substrate.

17. The micropump of claim 15, wherein the gap layer comprises any of Tungsten, Copper, Nickel, SiRN, SiN, Aluminum, Ag, Au or combinations of these materials.

18. The micropump of claim 15, wherein the first or second piezo electric layer stack includes at least a support layer, bottom electrode, piezoelectric layer, top electrode.

19. The micropump of claim 15, wherein the piezoelectric layer comprises any of AlN, AlSCN, PZT, KNN, PVDF.
